(19) United States
(12) Patent Application Publication
(10) Pub. No.: US 2025/0221184 A1
(43) Pub. Date: Jul. 3, 2025

(54) DISPLAY DEVICE

(71) Applicant: LG Display Co., Ltd., Seoul (KR)

(72) Inventor: KyungEon LEE, Paju-si (KR)

(73) Assignee: LG Display Co., Ltd., Seoul (KR)

(21) Appl. No.: 18/824,448

(22) Filed: Sep. 4, 2024

(30) Foreign Application Priority Data
Dec. 28, 2023 (KR) 10-2023-0194474

(51) Int. Cl. H10K 59/124; H10K 59/122; H10K 59/35

(52) U.S. Cl. CPC H10K 59/124; H10K 59/122; H10K 59/35

(57) ABSTRACT

A display device including a first overcoating layer disposed on a substrate; a first anode electrode disposed on the first overcoating layer to overlap a first light emitting area; a second anode electrode disposed on the first overcoating layer to overlap a second light emitting area; a current removal line disposed in a first non-light emitting area as an area between the first light emitting area and the second light emitting area; a first intermediate layer disposed to cover the current removal line, and including a first emitting layer; a charge generation layer disposed on the first intermediate layer; a second intermediate layer disposed on the charge generation layer, and including a second emitting layer; and a cathode electrode disposed on the second intermediate layer.

### CROSS-REFERENCE TO RELATED APPLICATION

This application claims priority to Korean Patent Application No. 10-2023-0194474, filed on Dec. 28, 2023, the entire contents of which is hereby expressly incorporated by reference into the present application.

### BACKGROUND

### Field

Embodiments of the present disclosure relate to a display device.

### Description of Related Art

As the information society develops, demands for display devices for displaying an image are increasing in various forms. Recently, various display devices such as a liquid crystal display device and an organic light emitting display device have been used.

A display device includes a display panel and driving circuits in which the display panel includes a plurality of subpixels.

### BRIEF SUMMARY

Accordingly, an object of the present disclosure is to provide a display device capable of preventing a light emitting phenomenon due to a leakage current.

Another object of the present disclosure is to provide a display device in which color coordinates are not distorted at a low grayscale.

Yet another object of the present disclosure is to provide a display device capable of improving the image quality of a display panel.

Still another object of the present disclosure is to provide a display device capable of low power consumption as the image quality of a display panel is improved.

To achieve these and other advantages and in accordance with the purpose of the present invention, as embodied and broadly described herein, the present disclosure provides in one aspect a display device having a substrate including a first light emitting area and a second light emitting area; a first overcoating layer disposed on the substrate; a first anode electrode disposed on the first overcoating layer to overlap the first light emitting area; a second anode electrode disposed on the first overcoating layer to overlap the second light emitting area; a current removal line disposed in a first non-light emitting area as an area between the first light emitting area and the second light emitting area; a first intermediate layer disposed to cover the current removal line, and including a first emitting layer; a charge generation layer disposed on the first intermediate layer; a second intermediate layer disposed on the charge generation layer, and including a second emitting layer; and a cathode electrode disposed on the second intermediate layer.

Further scope of applicability of the present invention will become apparent from the detailed description given hereinafter. However, the detailed description and specific examples, while indicating preferred embodiments of the invention, are given by illustration only, since various changes and modifications within the spirit and scope of the invention will become apparent to those skilled in the art from this detailed description.

### BRIEF DESCRIPTION OF DRAWINGS

The present invention will become more fully understood from the detailed description given hereinbelow and the accompanying drawings, which are given by illustration only, and thus are not limitative of the present invention, and wherein:

FIG. 1 is a system configuration diagram of a display device according to embodiments of the present disclosure.

FIG. 2 is a diagram illustrating a display panel according to embodiments of the present disclosure.

FIGS. 3 and 4 are diagrams of light emitting areas and non-light emitting areas according to embodiments of the present disclosure.

FIG. 5 is a diagram of a tandem intermediate layer (EL) according to embodiments of the present disclosure.

FIG. 6 is a diagram illustrating a lateral leakage current phenomenon according to embodiments of the present disclosure.

FIG. 7 is a diagram of current removal lines disposed in a non-light emitting area according to embodiments of the present disclosure.

FIGS. 8 to 11 are cross-sectional views of current removal lines disposed in a non-light emitting area according to embodiments of the present disclosure.

FIG. 12 is a diagram of current removal lines disposed in a non-light emitting area according to embodiments of the present disclosure.

FIG. 13 is a cross-sectional view of the current removal lines disposed in the non-light emitting area according to the embodiments of the present disclosure.

FIGS. 14 to 17 are diagrams of current removal lines disposed to overlap anode electrodes according to embodiments of the present disclosure.

FIG. 18 is a diagram of current removal lines disposed in a display panel according to embodiments of the present disclosure.

FIGS. 19 and 20 are diagrams of current removal lines in contact areas according to embodiments of the present disclosure.

FIG. 21 is a diagram of a current removal line disposed in a display panel according to embodiments of the present disclosure.

FIGS. 22 and 23 are diagrams of the disposition of current removal lines according to embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps”, etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes, etc. are mentioned, it should be considered that numerical values for elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “can”.

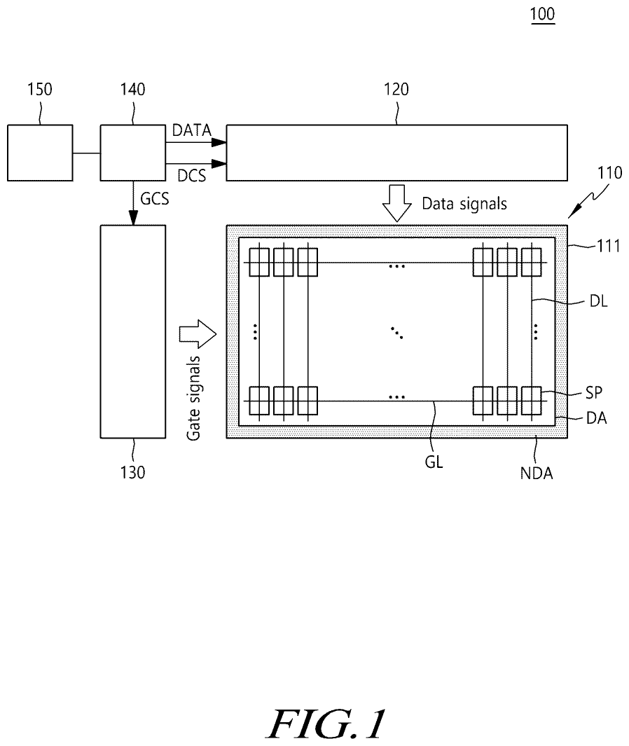

Hereinafter, various embodiments of the present disclosure will be described in detail with reference to accompanying drawings. In particular, FIG. 1 is a system configuration diagram of a display device 100 according to embodiments of the present disclosure.

Referring to FIG. 1, the display device 100 includes a display panel 110 and a display driving circuit as components for displaying an image. The display driving circuit includes a data driving circuit 120, a gate driving circuit 130 and a display controller 140, for example.

As shown in FIG. 1, the display panel 110 includes a substrate 111 and a plurality of subpixels SP disposed on the substrate 111. The substrate 111 includes a display area DA capable of displaying an image and a non-display area NDA located outside the display area DA. The subpixels SP for displaying an image are disposed in the display area DA, and the non-display area NDA can include a pad area (PA) located in a first direction from the display area DA. Further, the non-display area NDA is generally very small and can be referred to as a “bezel.”

For example, the non-display area NDA can include a first non-display area located outside the display area DA in the first direction, a second non-display area located outside the display area DA in a second direction intersecting the first direction, a third non-display area located outside the display area DA in a direction opposite to the first direction, and a fourth non-display area located outside the display area DA in a direction opposite to the second direction. One or two among the first to fourth non-display areas can include the pad area to which the data driving circuit 120 is connected or bonded. Also, two or three among the first to fourth non-display areas in which the pad area is not included is very small in size.

In another example, a boundary area between the display area DA and the non-display area NDA can be bent, and thus, the non-display area NDA can be located under the display area DA. In this instance, when a user looks at the display device 100 from the front, little or no non-display area NDA is visible to the user. Also, various types of signal lines for driving the subpixels SP can be disposed on the substrate 111 of the display panel 110.

In addition, the display device 100 according to the embodiments of the present disclosure can be a liquid crystal display device or the like, or a self-emissive display device in which the display panel 110 self-emits light. When the display device 100 is a self-emissive display device, each subpixel SP includes a light emitting element.

Further, the display device 100 according to the embodiments of the present disclosure can be an organic light emitting display device in which a light emitting element is implemented using an organic light emitting diode (OLED). In another example, the display device 100 according to the embodiments of the present disclosure can be an inorganic light emitting display device in which a light emitting element is implemented using an inorganic-based light emitting diode. In still another example, the display device 100 according to the embodiments of the present disclosure can be a quantum dot display device in which a light emitting element is implemented using quantum dots as semiconductor crystals which self-emit light.

In addition, the structure of the subpixels SP can vary depending on the type of the display device 100. For example, when the display device 100 is a self-emissive display device in which each subpixel SP self-emits light, each subpixel SP can include a self-emissive light emitting element, at least one transistor and at least one capacitor.

Further, the various types of signal lines can include a plurality of data lines DL which transfer data signals (also referred to as data voltages or image signals) and a plurality of gate lines GL which transfer gate signals (also referred to as scan signals). In addition, the data lines DL and the gate lines GL can intersect each other. Also, each data line DL can be disposed to extend in the first direction, and each gate line GL can be disposed to extend in the second direction. In addition, the first direction can be a column direction, and the second direction can be a row direction. Alternatively, the first direction can be a row direction, and the second direction can be a column direction. Hereinafter, for the sake of convenience in explanation, of the description describes each data line DL is disposed in a column direction and each gate line GL is disposed in a row direction.

In addition, the data driving circuit 120 for driving the data lines DL can output data signals to the data lines DL. Further, the data driving circuit 120 can receive image data DATA of a digital type from the display controller 140, convert the received image data DATA into data signals of an analog type, and output the data signals to the data lines DL.

For example, the data driving circuit 120 can be connected to the display panel 110 in a tape automated bonding (TAB) method, can be connected to bonding pads of the display panel 110 in a chip-on-glass (COG) or chip-on-panel (COP) method, or can be connected to the display panel 110 using a chip-on-film (COF) method.

Further, the data driving circuit 120 can be connected to one side (e.g., the upper side or the lower side) of the display panel 110. Alternatively, depending on a driving method, a panel design method, etc., the data driving circuit 120 can be connected to both sides (e.g., the upper side and the lower side) of the display panel 110, or can be connected to at least two sides of the four sides of the display panel 110. Further, the data driving circuit 120 can be connected to the outside of the display area DA of the display panel 110, or disposed in the display area DA of the display panel 110.

In addition, the gate driving circuit 130 for driving the gate lines GL output gate signals to the gate lines GL. The gate driving circuit 130 can be supplied with a first gate voltage corresponding to a turn-on level voltage and a second gate voltage corresponding to a turn-off level voltage along with various gate driving control signals GCS, can generate gate signals, and can supply the generated gate signals to the gate lines GL.

In the display device 100 according to the embodiments of the present disclosure, the gate driving circuit 130 can be embedded in the display panel 110 in a gate-in-panel (GIP) type. When the gate driving circuit 130 is a gate-in-panel (GIP) type, the gate driving circuit 130 can be formed on the substrate 111 of the display panel 110 during the manufacturing process of the display panel 110.

Further, the gate driving circuit 130 can be disposed in the display area DA of the display panel 110. For example, the gate driving circuit 130 can be disposed in a first partial area in the display area DA (e.g., a left area or a right area in the display area DA). In another example, the gate driving circuit 130 can be disposed in a first partial area in the display area DA (e.g., a left area or a right area in the display area DA) and a second partial area in the display area DA (e.g., the right area or the left area in the display area DA). Further, the gate driving circuit 130 which is embedded in the display panel 110 in a gate-in-panel (GIP) type is referred to as a “gate-in-panel circuit.”

In addition, the display controller 140 for controlling the data driving circuit 120 and the gate driving circuit 130 can control a driving timing for the data lines DL and a driving timing for the gate lines GL. The display controller 140 can supply a data driving control signal DCS to the data driving circuit 120 to control the data driving circuit 120, and can supply a gate driving control signal GCS to the gate driving circuit 130 to control the gate driving circuit 130. Further, the display controller 140 can receive input image data from a host system 150, and supply image data DATA to the data driving circuit 120 based on the input image data.

Also, the display controller 140 can be implemented as a component separate from the data driving circuit 120, or be implemented as an integrated circuit by being integrated with the data driving circuit 120. The display controller 140 can be a timing controller which is used in general display technology, can be a control device which includes a timing controller and is capable of further performing other control functions, can be a control device which is different from a timing controller, or can be a circuit in a control device. The display controller 140 can be implemented by various circuits or electronic parts such as an integrated circuit (IC), a field programmable gate array (FPGA), an application specific integrated circuit (ASIC) and a processor.

Further, the display controller 140 can be mounted on a printed circuit board, a flexible printed circuit or the like, and can be electrically connected to the data driving circuit 120 and the gate driving circuit 130 through the printed circuit board, the flexible printed circuit or the like. The display controller 140 can also transmit and receive signals to and from the data driving circuit 120 according to at least one predetermined interface. For example, the interface can include a low voltage differential signaling (LVDS) interface, an EPI (embedded clock point-point interface), a serial peripheral interface (SPI), etc.

In order to further provide a touch sensing function as well as an image display function, the display device 100 according to the embodiments of the present disclosure can include a touch sensor and a touch sensing circuit which, by sensing the touch sensor, detects whether a touch event has occurred by a touch object such as a finger or a pen or detects a touch location.

The touch sensing circuit can include a touch driving circuit which generates, and outputs touch sensing data by driving and sensing the touch sensor, and a touch controller which can detect the occurrence of a touch event or detect a touch location using the touch sensing data.

Further, the touch sensor can include a plurality of touch electrodes and a plurality of touch lines for electrically connecting the touch electrodes and the touch driving circuit.

In addition, the touch sensor can exist in the form of a touch panel outside the display panel 110, or can exist inside the display panel 110. When the touch sensor exists in the form of a touch panel outside the display panel 110, the touch sensor can be referred to as an external type. When the touch sensor is an external type, the touch panel and the display panel 110 can be separately manufactured and be coupled during an assembly process. The external type touch panel can include a substrate for a touch panel and a plurality of touch electrodes on the substrate for a touch panel.

When the touch sensor exists inside the display panel 110, the touch sensor can be formed on the substrate 111 together with signal lines and electrodes related with display driving during the process of manufacturing the display panel 110. The touch driving circuit can supply a touch driving signal to at least one of the touch electrodes, and can generate touch sensing data by sensing at least one of the touch electrodes.

Further, the touch sensing circuit can perform touch sensing in a self-capacitance sensing method or a mutual-capacitance sensing method. When the touch sensing circuit performs touch sensing in the self-capacitance sensing method, the touch sensing circuit can perform touch sensing based on the capacitance between each touch electrode and a touch object (e.g., a finger, a pen, etc.). According to the self-capacitance sensing method, each of the touch electrodes can serve as both a driving touch electrode and a sensing touch electrode. The touch driving circuit can also drive all or some of the touch electrodes, and can sense all or some of the touch electrodes.

When the touch sensing circuit performs touch sensing in the mutual-capacitance sensing method, the touch sensing circuit can perform touch sensing based on the capacitance between touch electrodes. According to the mutual-capacitance sensing method, the touch electrodes are divided into driving touch electrodes and sensing touch electrodes. The touch driving circuit can also drive the driving touch electrodes and sense the sensing touch electrodes.

In addition, the touch driving circuit and the touch controller included in the touch sensing circuit can be implemented as separate devices or can be implemented as a single device. Further, the touch driving circuit and the data driving circuit 120 can be implemented as separate devices or can be implemented as a single device. The display device 100 can further include a power supply circuit which supplies various types of power to the display driving circuit and/or the touch sensing circuit.

The display device 100 according to the embodiments of the present disclosure can be a mobile terminal such as a smart phone and a tablet or a monitor or a television (TV) of various sizes. However, the display device 100 according to the embodiments of the present disclosure is not limited thereto, and can be a display of various types and various sizes capable of displaying information or an image.

The display device 100 according to the embodiments of the present disclosure can further include an electronic device such as a camera (an image sensor) and a detection sensor. For example, the detection sensor can be a sensor which detects an object or a human body by receiving light such as infrared light, ultrasonic light and ultraviolet light.

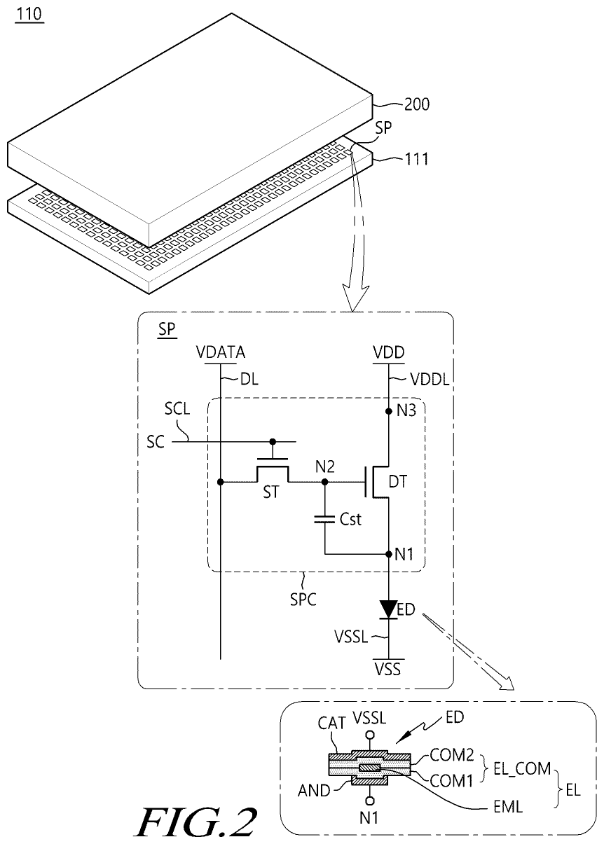

Next, FIG. 2 is a diagram showing a display panel 110 according to embodiments of the present disclosure. Referring to FIG. 2, the display panel 110 includes a substrate 111 on which a plurality of subpixels SP are disposed, and an encapsulation layer 200 on the substrate 111. The encapsulation layer 200 can also be referred to as an encapsulation substrate or an encapsulation part.

As shown in FIG. 2, when the display device 100 is a self-emissive display device, each o subpixel SP disposed on the substrate 111 can include a light emitting element ED and a subpixel circuit SPC for driving the light emitting element ED.

Further, as shown, the subpixel circuit SPC can include a plurality of pixel driving transistors for driving the light emitting element ED and at least one capacitor. In the present disclosure, the subpixel circuit SPC can drive the light emitting element ED by supplying driving current to the light emitting element ED at a predetermined timing. The light emitting element ED can also be driven by the driving current to emit light.

Further, the pixel driving transistors can include a driving transistor DT for driving the light emitting element ED and a scan transistor ST which is turned on or off according to a scan signal SC. Also, the driving transistor DT can supply driving current to the light emitting element ED.

In addition, the scan transistor ST can control the electrical state of a corresponding node in the subpixel circuit SPC or control the state or operation of the driving transistor DT. The at least one capacitor can also include a storage capacitor Cst for maintaining a constant voltage during a frame.

In order to drive the subpixel SP, a data signal VDATA as an image signal, the scan signal SC as a gate signal, etc. can be applied to the subpixel SP. Further, in order to drive the subpixel SP, common pixel driving voltages including a first common driving voltage VDD and a second common driving voltage VSS can be applied to the subpixel SP.

In addition, the light emitting element ED can include an anode AND, a light emitting element intermediate layer EL and a cathode CAT. The light emitting element intermediate layer EL can be disposed between the anode AND and the cathode CAT.

When the light emitting element ED is an organic light emitting element, the light emitting element intermediate layer EL can include an emitting layer EML, a first common intermediate layer COM1 between the anode AND and the emitting layer EML, and a second common intermediate layer COM2 between the emitting layer EML and the cathode CAT. Further, the emitting layer EML can be disposed in each subpixel SP. In comparison with this, the first common intermediate layer COM1 and the second common intermediate layer COM2 can be disposed in common over a plurality of subpixels SP. Also, the emitting layer EML can be disposed in each light emitting area, and the first common intermediate layer COM1 and the second common intermediate layer COM2 can be disposed in common over a plurality of light emitting areas and a non-light emitting area. The first common intermediate layer COM1 and the second common intermediate layer COM2 are also collectively referred to as a common intermediate layer EL_COM.

In more detail, the first common intermediate layer COM1 can include a hole injection layer (HIL) and a hole transport layer (HTL), and the second common intermediate layer COM2 can include an electron transport layer (ETL) and an electron injection layer (EIL). Further, the hole injection layer can inject holes from the anode AND into the hole transport layer, the hole transport layer can transport holes to the emitting layer EML, the electron injection layer can inject electrons from the cathode CAT into the electron transport layer, and the electron transport layer can transport electrons to the emitting layer EML.

Also, the cathode CAT can be electrically connected to a second common driving voltage line VSSL. Thus, the second common driving voltage VSS, which is a type of common pixel driving voltage, can be applied to the cathode CAT through the second common driving voltage line VSSL. Further, the anode AND can be electrically connected to a first node N1 of the driving transistor DT of each subpixel SP. In the present disclosure, the second common driving voltage VSS can also be referred to as a base voltage VSS, and the second common driving voltage line VSSL can also be referred to as a base voltage line VSSL.

In addition, the anode AND can be a pixel electrode which is disposed in each subpixel SP, and the cathode CAT can be a common electrode which is disposed in common in a plurality of subpixels SP. In another example, the cathode CAT can be a pixel electrode which is disposed in each subpixel SP, and the anode AND can be a common electrode which is disposed in common in a plurality of subpixels SP. Hereinafter, for the sake of convenience in explanation, the anode AND is a pixel electrode and the cathode CAT is a common electrode.

In addition, each light emitting element ED can be composed of overlapping portions of the anode AND, the light emitting element intermediate layer EL and the cathode CAT. A predetermined light emitting area can be formed by each light emitting element ED. For example, the light emitting area of each light emitting element ED can include an area where the anode AND, the light emitting element intermediate layer EL and the cathode CAT overlap.

Also, the light emitting element ED can be an organic light emitting diode (OLED), an inorganic-based light emitting diode (LED) or a quantum dot light emitting element. When the light emitting element ED is an organic light emitting diode (OLED), the light emitting element intermediate layer EL in the light emitting element ED can include a light emitting element intermediate layer EL which includes an organic material.

In addition, the driving transistor DT is for supplying driving current to the light emitting element ED. As shown in FIG. 2, the driving transistor DT can be connected between a first common driving voltage line VDDL and the light emitting element ED.

Further, as shown, the driving transistor DT can include the first node N1 which is electrically connected to the light emitting element ED, a second node N2 to which the data signal VDATA can be applied, and a third node N3 to which the first common driving voltage VDD is applied from the first common driving voltage line VDDL.

In the driving transistor DT, the second node N2 can be a gate node, the first node N1 can be a source node or a drain node, and the third node N3 can be a drain node or a source node. Hereinbelow, for the sake of convenience in explanation, it will be described as an example that, in the driving transistor DT, the second node N2 is a gate node, the first node N1 is a source node and the third node N3 is a drain node.

Also, the scan transistor ST included in the subpixel circuit SPC illustrated in FIG. 2 can be a switching transistor for transferring the data signal VDATA as an image signal to the second node N2 which is the gate node of the driving transistor DT. The scan transistor ST can be on-off controlled by the scan signal SC as a gate signal applied through a scan line SCL which is a type of gate line GL, and thus, can control the electrical connection between the second node N2 of the driving transistor DT and a data line DL. In addition, the drain electrode or the source electrode of the scan transistor ST can be electrically connected to the data line DL, the source electrode or the drain electrode of the scan transistor ST can be electrically connected to the second node N2 of the driving transistor DT, and the gate electrode of the scan transistor ST can be electrically connected to the scan line SCL.

Further, the storage capacitor Cst can be electrically connected between the first node N1 and the second node N2 of the driving transistor DT. The storage capacitor Cst can include a first capacitor electrode which is electrically connected to the first node N1 of the driving transistor DT or corresponds to the first node N1 of the driving transistor DT, and a second capacitor electrode which is electrically connected to the second node N2 of the driving transistor DT or corresponds to the second node N2 of the driving transistor DT.

Also, the storage capacitor Cst may not be a parasitic capacitor (e.g., Cgs or Cgd) which is an internal capacitor likely to exist between the first node N1 and the second node N2 of the driving transistor DT but an external capacitor which is intentionally designed outside the driving transistor DT.

Also, each of the driving transistor DT and the scan transistor ST can be an n-type transistor or a p-type transistor. The display panel 110 can also have a top emission structure or a bottom emission structure.

When the display panel 110 has the top emission structure, at least a portion of the subpixel circuit SPC can overlap at least a portion of the light emitting element ED in a vertical direction. When the display panel 110 has the bottom emission structure, the subpixel circuit SPC does not overlap the light emitting element ED in a vertical direction.

As illustrated in FIG. 2, the subpixel circuit SPC can have a 2T (transistor) 1C (capacitor) structure including two transistors DT and ST and one capacitor Cst. Also, the subpixel circuit SPC can further include at one or more transistor and capacitors.

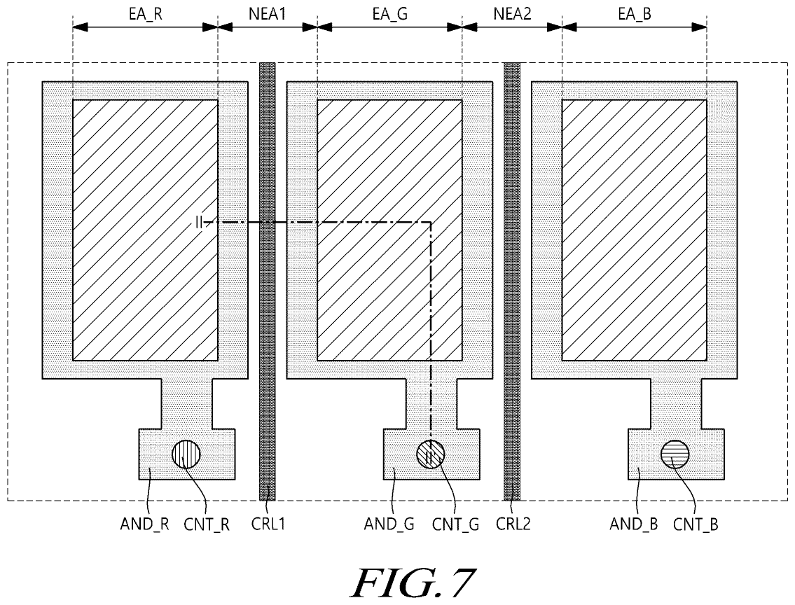

For example, the subpixel circuit SPC can have a 3TIC structure including three transistors and one capacitor. In this instance, the display panel 110 can further include a reference voltage line to which a reference voltage is supplied. A sensing transistor can also be electrically connected between the first node N1 and the reference voltage line. One reference voltage line can be electrically connected to four subpixels. That is, four subpixels can share one reference voltage line. The reference voltage line can also be disposed to pass between light emitting areas EA shown in FIG. 7. The reference voltage line can be disposed to extend in the same direction as current removal lines CRL1 and CRL2 shown in FIG. 7.

In addition, the subpixel circuit SPC can have an 8TIC structure including eight transistors and one capacitor. In another example, the subpixel circuit SPC can have a 6T2C structure including six transistors and two capacitors. In still another example, the subpixel circuit SPC can have a 7TIC structure including seven transistors and one capacitor.

Further, the type and number of gate signals supplied to the subpixel SP and the type and number of gate lines can vary depending on the structure of the subpixel circuit SPC. Further, the types and number of common pixel driving voltages supplied to the subpixel SP can vary depending on the structure of the subpixel circuit SPC.

Because circuit elements (in particular, the light emitting element ED implemented by an organic light emitting diode (OLED) including an organic material) in each subpixel SP are vulnerable to external moisture or oxygen, the encapsulation layer 200 for preventing external moisture or oxygen from penetrating into the circuit elements (in particular, the light emitting element ED) can be disposed in the display panel 110. The encapsulation layer 200 can be configured in various shapes to prevent light emitting elements ED from contacting moisture or oxygen.

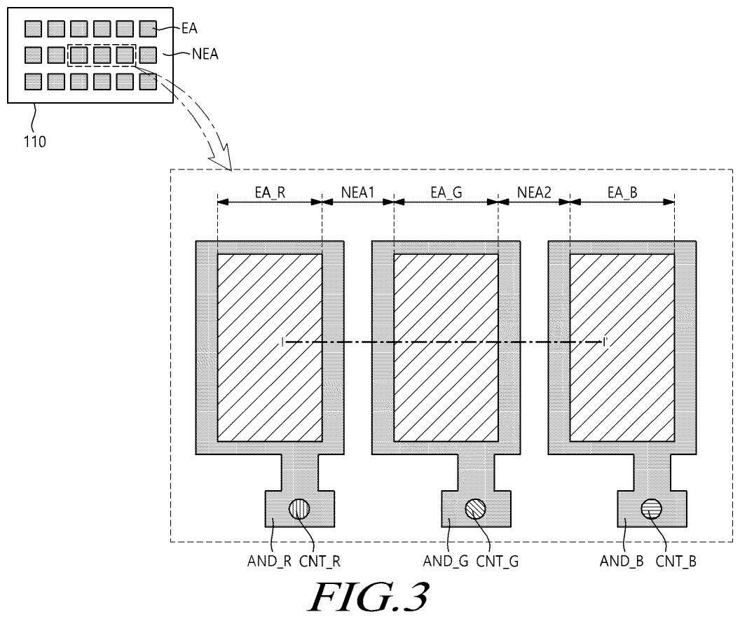

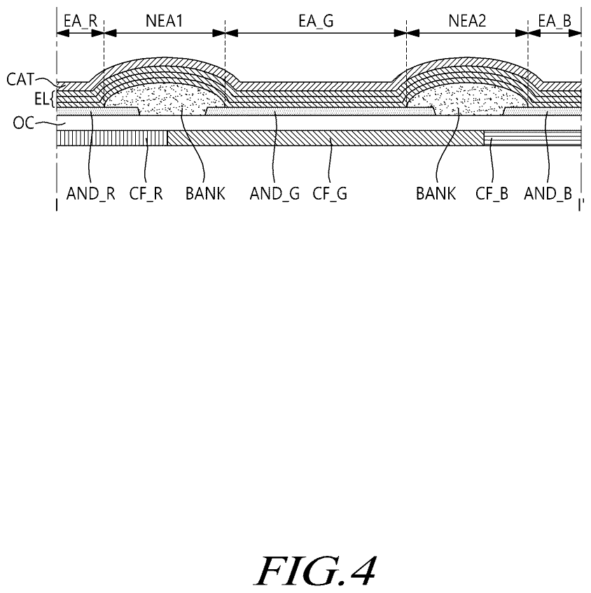

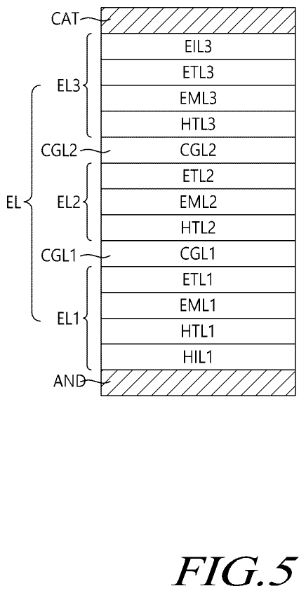

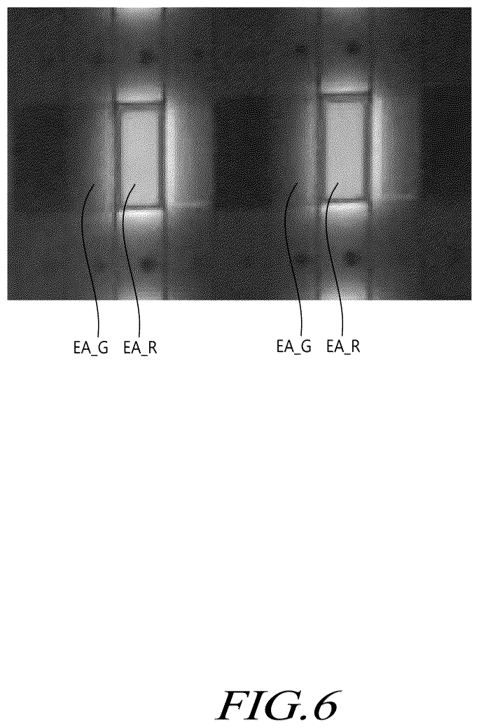

Next, FIGS. 3 and 4 are diagrams of light emitting areas EA and non-light emitting areas NEA, FIG. 5 is a diagram showing a tandem intermediate layer EL, and FIG. 6 is a diagram illustrating a lateral leakage current phenomenon according to embodiments of the present disclosure.

Referring to FIG. 3, the display panel 110 can include a plurality of light emitting areas EA and a plurality of non-light emitting areas NEA. The light emitting areas EA can be areas where light is emitted and where light emitting elements are disposed. The non-light emitting areas NEA can be areas which are not the light emitting areas EA and be areas where circuits for driving light emitting elements are disposed.

Referring to FIG. 3, for the sake of convenience in explanation, the light emitting areas EA include 18 light emitting areas EA. As shown, the light emitting areas EA can be disposed in the form of an m*n matrix. For example, the light emitting areas EA can be disposed in three horizontal directions and six vertical directions. Thus, 18 light emitting areas EA are shown.

FIG. 3 illustrates three light emitting areas EA by being enlarged. As shown in FIG. 3, the light emitting areas EA can include a first light emitting area EA_R, a second light emitting area EA_G and a third light emitting area EA_B.

The first light emitting area EA_R can be disposed to overlap a first anode electrode AND_R. The first anode electrode AND_R can be electrically connected to a driving transistor through a first contact hole CNT_R. The driving transistor can flow driving current to the first anode electrode AND_R, and a light emitting element can emit light based on the driving current to the first light emitting area EA_R. In addition, as shown in FIG. 3, the first light emitting area EA_R can be an area where red light is expressed.

Further, the second light emitting area EA_G can be disposed to overlap a second anode electrode AND_G electrically connected to a driving transistor through a second contact hole CNT_G. The driving transistor can flow driving current to the second anode electrode AND_G, and a light emitting element can emit light based on the driving current to the second light emitting area EA_G. As shown, the second light emitting area EA_G can be an area where green light is expressed.

Further, the third light emitting area EA_B can be disposed to overlap a third anode electrode AND_B electrically connected to a driving transistor through a third contact hole CNT_B. The driving transistor can flow driving current to the third anode electrode AND_B, and a light emitting element can emit light based on the driving current to the third light emitting area EA_B. As shown, the third light emitting area EA_B can be an area where blue light is expressed.

FIG. 3 illustrates a line I-I′ on the first light emitting area EA_R, the second light emitting area EA_G and the third light emitting area EA_B, and FIG. 4 is a cross-sectional view taken along the line I-I′. Referring to FIG. 4, the non-light emitting areas NEA can be areas between the first light emitting area EA_R, the second light emitting area EA_G and the third light emitting area EA_B.

In addition, the first anode electrode AND_R, the second anode electrode AND_G and the third anode electrode AND_B can be disposed on an overcoating layer OC. As shown in FIG. 4, the first anode electrode AND_R can be disposed to overlap the first light emitting area EA_R. Also, a portion of the first anode electrode AND_R can be disposed to overlap the non-light emitting area NEA. A portion of the first anode electrode AND_R can also be disposed to overlap a bank BANK. Also, the first anode electrode AND_R can be disposed to overlap the tandem intermediate layer EL.

In addition, as shown in FIG. 4, the second anode electrode AND_G can be disposed to overlap the second light emitting area EA_G. Also, a portion of the second anode electrode AND_G can be disposed to overlap the non-light emitting area NEA. Further, a portion of the second anode electrode AND_G can be disposed to overlap the bank BANK. The second anode electrode AND_G can also be disposed to overlap the tandem intermediate layer EL.

Similarly, the third anode electrode AND_B can be disposed to overlap the third light emitting area EA_B. Also, a portion of the third anode electrode AND_B can be disposed to overlap the non-light emitting area NEA. A portion of the third anode electrode AND_B can also be disposed to overlap the bank BANK. In addition, the third anode electrode AND_B can be disposed to overlap the tandem intermediate layer EL.

Referring to FIG. 4, the bank BANK can be disposed in the non-light emitting area NEA. After the bank BANK is entirely deposited on the anode electrodes AND, portions of the bank BANK corresponding to the light emitting areas EA can be removed by being etched.

In addition, the tandem intermediate layer EL can be disposed to cover the anode electrodes AND and the bank BANK. The tandem intermediate layer EL can also be a layer which emits light.

In addition, a cathode electrode CAT can be disposed on the tandem intermediate layer EL. In particular, the cathode electrode CAT can be an electrode to which a base voltage or a common voltage is supplied. The cathode electrode CAT can also be entirely deposited on the tandem intermediate layer EL.

When current is supplied to the anode electrodes AND, light can be emitted through the tandem intermediate layer EL contacting the anode electrodes AND. Emitted light can pass through color filters CF_R, CF_G and CF_B which are disposed below the anode electrodes AND. Emitted light can express a color corresponding to a color filter. In other words, the display device 100 can emit light in a bottom emission method. As shown in FIG. 4, the tandem intermediate layer EL can include a plurality of intermediate layers capable of emitting light. The tandem intermediate layer EL can thus be referred to as a stack structure. Referring to FIG. 5, a specific structure of the tandem intermediate layer EL can be seen.

Next, referring to FIG. 5, the tandem intermediate layer EL is a three-stack structure including three intermediate layers EL1, EL2 and EL3. For the sake of convenience in explanation, the following description will be made on the assumption that the tandem intermediate layer EL includes three intermediate layers EL1, EL2 and EL3. However, the tandem intermediate layer EL can include three or more intermediate layers, and can be formed as a four-stack structure or a five-stack structure.

Referring to FIG. 5, the tandem intermediate layer EL can be disposed between the anode electrode AND and the cathode electrode CAT. In addition, the tandem intermediate layer EL can include a first intermediate layer EL1, a first charge generation layer CGL1, a second intermediate layer EL2, a second charge generation layer CGL2, and a third intermediate layer EL3.

Also, the first intermediate layer EL1 can be disposed on the anode electrode AND. In addition, the first intermediate layer EL1 can be composed of a structure in which a first hole injection layer HIL1, a first hole transport layer HTL1, a first emitting layer EML1 which emits light of a first color and a first electron transport layer ETL1 are sequentially stacked, but is not limited thereto. The first emitting layer EML1 can be at least one of a red light emitting layer which emits red light, a green light emitting layer which emits green light, a blue light emitting layer which emits blue light and a yellow light emitting layer which emits yellow light, but is not necessarily limited thereto.

Referring to FIG. 5, the first charge generation layer CGL1 can be disposed on the first intermediate layer EL1. Also, the first charge generation layer CGL1 can be composed of a structure in which an N-type charge generation layer for providing electrons to the first intermediate layer EL1 and a P-type charge generation layer for providing holes to the second intermediate layer EL2 are stacked.

In addition, the second intermediate layer EL2 can be disposed on the first charge generation layer CGL1. Further, the second intermediate layer EL2 can be composed of a structure in which a second hole transportation layer HTL2, a second emitting layer EML2 which emits light of a second color, and a second electron transport layer ETL2 are sequentially stacked, but is not limited thereto. The second emitting layer EML2 can also be at least one of a red light emitting layer which emits red light, a green light emitting layer which emits green light, a blue light emitting layer which emits blue light and a yellow light emitting layer which emits yellow light, but is not necessarily limited thereto. The second emitting layer EML2 can emit light of a color different from that of the first emitting layer EML1. For example, the first emitting layer EML1 can be a blue light emitting layer which emits blue light, and the second emitting layer EML2 can be a yellow light emitting layer which emits yellow light. In another example, the first emitting layer EML1 can be a blue light emitting layer which emits blue light, and the second emitting layer EML2 can be a red light emitting layer which emits red light or a green light emitting layer which emits green light.

As shown in FIG. 5, the second charge generation layer CGL2 can be disposed on the second intermediate layer EL2, and the third intermediate layer EL3 can be disposed on the second charge generation layer CGL2. In addition, the third intermediate layer EL3 can be composed of a structure in which a third hole transport layer HTL3, a third emitting layer EML3 which emits light of a third color, a third electron transport layer ETL3 and a third electron injection layer EIL3 are sequentially stacked, but is not necessarily limited thereto.

Further, the third emitting layer EML3 can be at least one of a red light emitting layer which emits red light, a green light emitting layer which emits green light and a blue light emitting layer which emits blue light, but is not limited thereto. The third emitting layer EML3 can also emit light of a color different from those of the first emitting layer EML1 and the second emitting layer EML2. For example, the first emitting layer EML1 can be a blue light emitting layer which emits blue light, the second emitting layer EML2 can be a red light emitting layer which emits red light, and the third emitting layer EML3 can be a green light emitting layer which emits green light. The order of colors emitted by the first emitting layer EML1, the second emitting layer EML2 and the third emitting layer EML3 can be changed in various ways.

As shown in FIG. 5, the cathode electrode CAT can be disposed on the third intermediate layer EL3. The cathode electrode CAT can be a common layer which is formed in common in the subpixels SP. The cathode electrode CAT can be formed on the tandem intermediate layer EL to provide electrons to the tandem intermediate layer EL.

Next, FIG. 6 illustrates a lateral leakage current phenomenon. In more detail, the lateral leakage current phenomenon refers to a phenomenon in which light is emitted not only through a light emitting area EA controlled to emit light but also through a light emitting area EA not controlled to emit light. The lateral leakage current phenomenon will be described with reference to FIG. 6.

Referring to FIG. 6, the first light emitting area EA_R is an area which is controlled to emit light. the first light emitting area EA_R can be an area where red light is emitted. Referring to FIG. 6, the second light emitting area EA_G is an area which is adjacent to the red light emitting area EA_R and can be an area where green light is emitted.

Referring to FIG. 6, the second light emitting area EA_G is an area which is not controlled to emit light, but is emitting light. Namely, the lateral leakage current phenomenon occurs in the second light emitting area EA_G. The lateral leakage current phenomenon shown in FIG. 6 occurs by the charge generation layers CGL1 and CGL2 shown in FIG. 5. The self-resistance of the charge generation layers CGL1 and CGL2 is relatively low, and is easy for current to flow. FIG. 5 shows the tandem intermediate layer EL including three intermediate layers EL1, EL2 and EL3, which has the same structure as the tandem intermediate layer EL shown in FIG. 4.

Thus, current supplied to the second anode electrode AND_G can be supplied to the charge generation layers CGL1 and CGL2 of the tandem intermediate layer EL corresponding to the second light emitting area EA_G. The current supplied to the charge generation layers CGL1 and CGL2 corresponding to the second light emitting area EA_G can flow to the charge generation layers CGL1 and CGL2 corresponding to the first light emitting area EA_R. This current can be referred to as lateral leakage current. In addition, current supplied to the charge generation layers CGL1 and CGL2 corresponding to the second light emitting area EA_G can flow to the charge generation layers CGL1 and CGL2 corresponding to the third light emitting area EA_B, and this current can be referred to as lateral leakage current.

Due to the lateral leakage current, light can be emitted from the first light emitting area EA_R or the third light emitting area EA_B. That is, the charge generation layer CGL can be disposed to overlap the light emitting areas EA, and a lateral leakage current phenomenon can occur due to lateral leakage current flowing through the charge generation layer CGL. Accordingly, a problem that color coordinates are distorted at a low grayscale can also occur. In this consideration, embodiments of the present disclosure provide a display device in which a light emitting phenomenon due to lateral leakage current can be prevented.

In particular, embodiments of the present disclosure provides a display device in which color coordinates are not distorted at a low grayscale, the image quality is improved and with a lower power consumption as the image quality of the display panel 110 is improved.

In particular, FIG. 7 is a diagram of current removal lines CRL disposed in a non-light emitting area NEA according to embodiments of the present disclosure. Referring to FIG. 7, the display device 100 can include a plurality of light emitting areas EA, a plurality of non-light emitting areas NEA and a plurality of current removal lines CRL. Among the features of the display device 100 shown in FIG. 7, descriptions of features that are the same as those of the display device 100 shown in FIG. 3 are omitted.

Referring to FIG. 7, the current removal lines CRL can be disposed between the light emitting areas EA and in the non-light emitting areas NEA. In more detail, a first current removal line CRL1 can be disposed between a first light emitting area EA_R and a second light emitting area EA_G. In addition, the first current removal line CRL1 can be disposed in a first non-light emitting area NEA1. A data line (can also be disposed in the first non-light emitting area NEA1 and can be a voltage line to which a data voltage is supplied.

Referring to FIG. 7, a second current removal line CRL2 can be disposed between the second light emitting area EA_G and a third light emitting area EA_B. As shown, the second current removal line CRL2 can be disposed in a second non-light emitting area NEA2. A reference voltage line can be disposed in the second non-light emitting area NEA2 and can be a line to which a reference voltage is supplied.

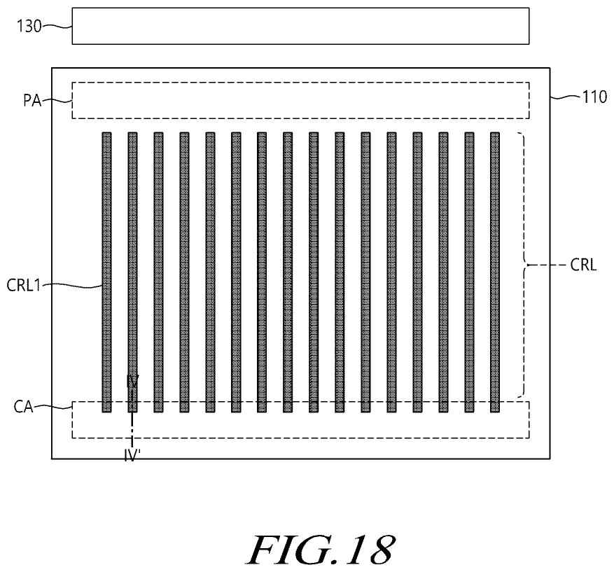

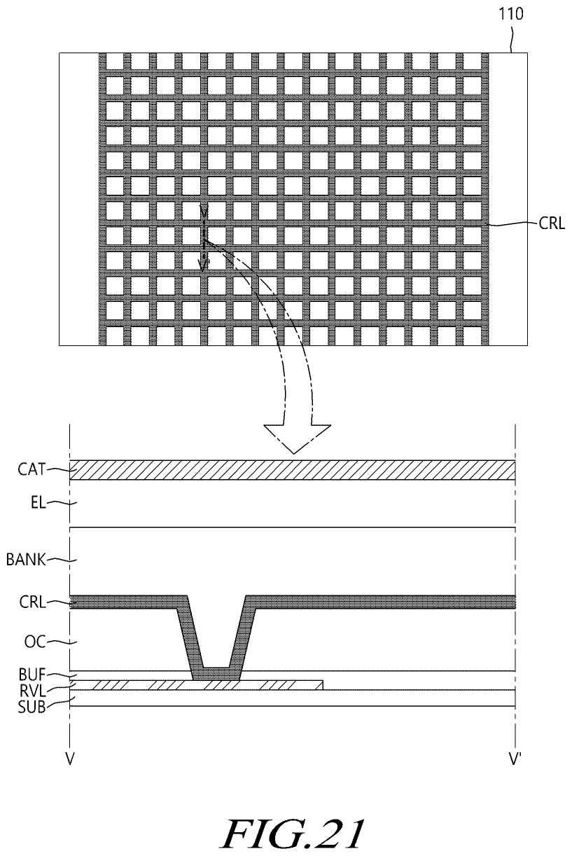

Further, the plurality of current removal lines CRL can be disposed in a stripe shape shown in FIG. 18 or a mesh shape shown in FIG. 21. After describing the cross-sectional view of the current removal line CRL, the disposition shape of the current removal lines CRL will be described.

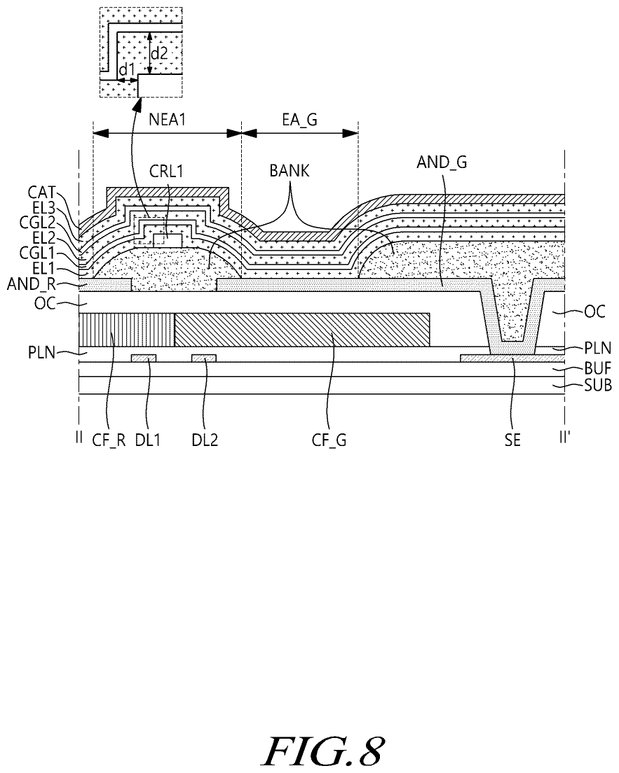

As the current removal line CRL is disposed in the non-light emitting area NEA, the current removal line CRL can remove leakage current flowing through the charge generation layer CGL. In more detail, FIG. 7 illustrates a line II-II′ and FIGS. 8-11 show cross-sectional views taken along the line II-II′. The current removal line CRL which removes leakage current will be described in more detail referring to FIGS. 8-11.

In particular, FIGS. 8 to 11 are cross-sectional views of current removal lines CRL disposed in a non-light emitting area NEA according to embodiments of the present disclosure. FIG. 8 illustrates a portion of the cross-sectional view of the display device 100 including the current removal line CRL.

Referring to FIG. 8, a substrate SUB can be disposed at the bottom of the display panel 110. Also, a buffer layer BUF can be disposed on the substrate SUB and can be an insulating layer. In addition, a first data line DL1 and a second data line DL2 can be disposed on the buffer layer BUF, but may be disposed in the non-light emitting area NEA.

As shown in FIG. 8, a source electrode SE can be disposed on the buffer layer BUF and can be the source electrode SE of a driving transistor. Alternatively, the source electrode SE can be an electrode which is electrically connected to the source electrode SE of a driving transistor. Further, a planarization layer PLN can be disposed to cover the buffer layer BUF, the first data line DL1, the second data line DL2 and a reference voltage line RVL. The planarization layer PLN can be an insulating layer. The planarization layer PLN can also include a contact hole for electrically connecting electrodes disposed on and under the planarization layer PLN.

As shown in FIG. 8, a first color filter CF_R can be disposed on the planarization layer PLN. The first color filter CF_R can be a color filter for expressing red. The first color filter CF_R can also be disposed between an overcoating layer OC and the substrate SUB to overlap a first anode electrode AND_R.

Referring to FIG. 8, a second color filter CF_G can be disposed on the planarization layer PLN. In addition, the second color filter CF_G can be a color filter for expressing green. The second color filter CF_G can also be disposed between the overcoating layer OC and the substrate SUB to overlap a second anode electrode AND_G.

Further, the second color filter CF_G can be disposed in contact with the first color filter CF_R. The second color filter CF_G can also be disposed side by side with the first color filter CF_R.

As shown in FIG. 8, the overcoating layer OC can be disposed to cover the first color filter CF_R, the second color filter CF_G and the planarization layer PLN. The overcoating layer OC can include a contact hole for electrically connecting electrodes disposed on and under the overcoating layer OC.

In addition, the first anode electrode AND_R can be disposed on the overcoating layer OC, and the first anode electrode AND_R can be disposed on the overcoating layer OC to overlap the first light emitting area EA_R. Further, the second anode electrode AND_G can be disposed on the overcoating layer OC and can be disposed in contact with the source electrode SE through the contact hole of the overcoating layer OC. The second anode electrode AND_G can also be disposed on the overcoating layer OC to overlap the second light emitting area EA_G.

Referring to FIG. 8, a bank BANK can be deposited on an entire surface to cover the anode electrodes AND and the overcoating layer OC. In the bank BANK deposited on the entire surface, portions corresponding to the light emitting areas EA can be removed by being etched.

As shown in FIG. 8, the bank BANK can be disposed to overlap the non-light emitting area NEA. The bank BANK which overlaps the non-light emitting area NEA can also be disposed to overlap the first data line DL1, the second data line DL2, the first color filter CF_R and the second color filter CF_G.

Referring to FIG. 8, the bank BANK which overlaps the non-light emitting area NEA can be disposed to overlap the current removal line CRL. Further, the current removal line CRL can be disposed in the non-light emitting area NEA. Also, the current removal line CRL can be disposed on the bank BANK which overlaps the non-light emitting area NEA.

As shown in FIG. 8, after the current removal line CRL is disposed, a tandem intermediate layer EL can be deposited on an entire surface. Further, the tandem intermediate layer EL can include a first intermediate layer EL1, a first charge generation layer CGL1, a second intermediate layer EL2, a second charge generation layer CGL2 and a third intermediate layer EL3. Also, a cathode electrode CAT can be disposed to cover the tandem intermediate layer EL.

In addition, the current removal line CRL can be disposed adjacent to the first charge generation layer CGL1. As the current removal line CRL is disposed adjacent to the first charge generation layer CGL1, an electromagnetic field can be formed between the current removal line CRL and the first charge generation layer CGL1. By the electromagnetic field, leakage current flowing through the first charge generation layer CGL1 can be transferred to the current removal line CRL.

In more detail, referring to FIG. 8, a first distance d1 from the side surface of the current removal line CRL to the first charge generation layer CGL1 can be shorter than a second distance d2 from the upper surface of the current removal line CRL to the first charge generation layer CGL1. For example, the first distance d1 can be 200 Angstroms, whereas the second distance d2 can be 900 Angstroms. In other words, when the current removal line CRL is disposed, the side surface of the current removal line CRL is formed close to the first charge generation layer CGL1, and accordingly, an electromagnetic field can be formed between the current removal line CRL and the first charge generation layer CGL1.

In addition, the current removal line CRL can have a vertical shape or a reversely tapered shape. In this instance, a stronger electromagnetic field can be formed between the current removal line CRL and the first charge generation layer CGL1. The current removal line CRL can also have a tapered shape.

Further, the higher the electrical conductivity of the current removal line CRL is, the faster the leakage current of the first charge generation layer CGL1 can be transferred to the current removal line CRL. For example, the current removal line CRL can include metal oxide such as indium-tin oxide (ITO), indium-zinc oxide (IZO), indium-tin-zinc oxide (ITZO) and indium-gallium-zinc oxide (IGZO). Alternatively, the current removal line CRL can include doped amorphous silicon (a-Si), doped polycrystalline silicon (poly-Si), etc.

When a low voltage is supplied to the current removal line CRL, the leakage current of the first charge generation layer CGL1 can be transferred more quickly to the current removal line CRL. For example, the current removal line CRL can be supplied with a base voltage or a reference voltage.

The thickness of the tandem intermediate layer EL can be approximately 4700 Angstroms. Also, the thickness of the current removal line CRL can be 1000 Angstroms or less. As the thickness of the current removal line CRL is designed to be equal to or less than 1000 Angstroms, the cathode electrode CAT can be stably disposed without the occurrence of cracks. As a leakage current phenomenon is prevented, a problem of color gamut reduction at a low grayscale can be solved.

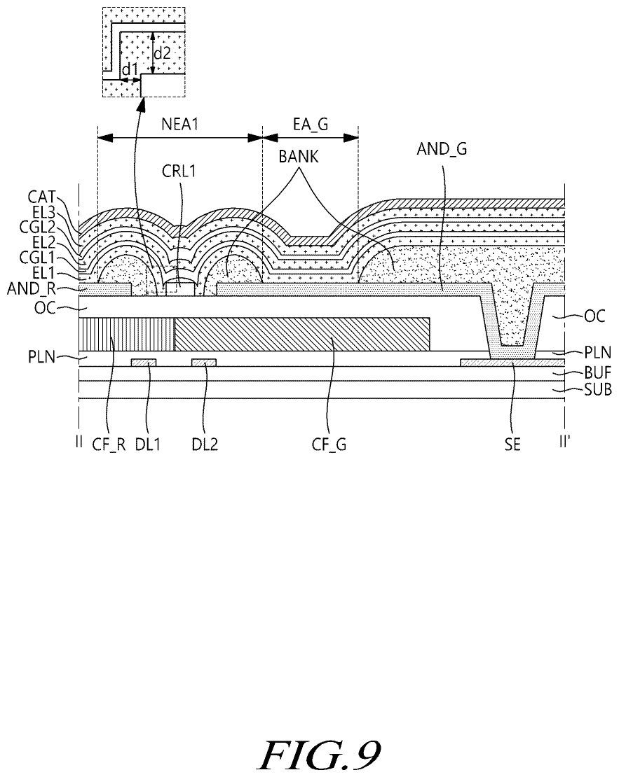

Next, FIG. 9 illustrates a portion of the cross-sectional view of the display device 100 including the current removal line CRL. A bank BANK shown in FIG. 9 has a structural difference from the bank BANK shown in FIG. 8. Among the components of the display device 100 shown in FIG. 9, descriptions of features that are the same as those of the components of the display device 100 shown in FIG. 8 can be omitted.

Referring to FIG. 9, the center portion of the bank BANK corresponding to a first non-light emitting area NEA1 can be removed by being etched. When viewed on the cross-sectional view, FIG. 9 illustrates the center portion of the bank BANK corresponding to the first non-light emitting area NEA1 is etched and the bank BANK remains on the left and right sides of the etched center portion.

As shown in FIG. 9, the current removal line CRL can be disposed in the center portion of the bank BANK which is etched in the first non-light emitting area NEA1. Further, the bank BANK is disposed in the first non-light emitting area NEA1 so that an area of the bank BANK is removed by being etched between the first anode electrode AND_R and the second anode electrode AND_G. In addition, the current removal line CRL can be disposed in the etched area of the bank BANK.

Referring to FIG. 9, after the current removal line CRL is disposed, the tandem intermediate layer EL can be deposited on an entire surface. As shown, the tandem intermediate layer EL can include a first intermediate layer EL1, a first charge generation layer CGL1, a second intermediate layer EL2, a second charge generation layer CGL2 and a third intermediate layer EL3. The cathode electrode CAT can be disposed to cover the tandem intermediate layer EL.

In addition, as shown in FIG. 9, a first distance d1 from the side surface of the current removal line CRL to the first charge generation layer CGL1 can be shorter than a second distance d2 from the upper surface of the current removal line CRL to the first charge generation layer CGL1. As an electromagnetic field is formed between the current removal line CRL and the first charge generation layer CGL1, leakage current flowing through the first charge generation layer CGL1 can be removed through the current removal line CRL.

In addition, the bank BANK in FIG. 9 can be made of a transparent material such as a polyamide resin, polyimide resin, etc., but is not limited thereto. When the bank is made of a transparent material, the viewing angle characteristics of the display device 100 can be improved.

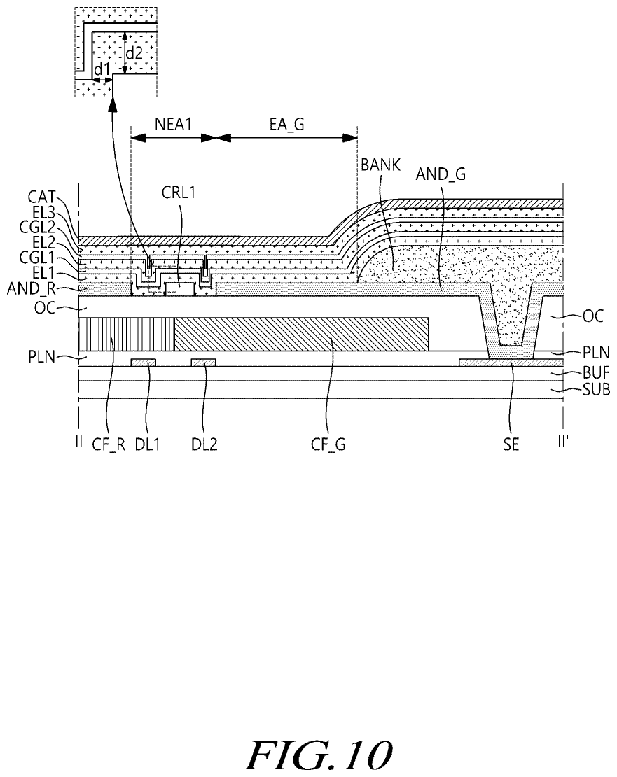

Next, FIG. 10 illustrates a portion of the cross-sectional view of the display device 100 including the current removal line CRL. Referring to FIG. 10, a bank BANK shown in FIG. 10 has a structural difference from the bank BANK shown in FIG. 8. Among the components of the display device 100 shown in FIG. 10, descriptions of features that are the same as those of the components of the display device 100 shown in FIG. 8 can be omitted.

Referring to FIG. 10, the current removal line CRL can be disposed in the first non-light emitting area NEA1 in contact with the overcoating layer OC. When viewed on the cross-sectional view, FIG. 10 illustrates the first anode electrode AND_R can be disposed on the left side of the current removal line CRL, and the second anode electrode AND_G can be disposed on the right side of the current removal line CRL.

Referring to FIG. 10, the bank BANK corresponding to the first non-light emitting area NEA1 can be entirely etched and removed. Further, the bank BANK may not exist in the first non-light emitting area NEA1.

In addition, the bank BANK can cover the first anode electrode AND_R, but may not be disposed in the first non-light emitting area NEA1. Also, a structure in which the bank BANK does not exist in the first non-light emitting area NEA1 can be referred to as a “bankless” structure. In addition, as shown in FIG. 7, the light emitting areas EA are disposed in a horizontal direction and a circuit area for driving a light emitting area EA can be disposed in the horizontal direction. When viewed on the plan view of FIG. 7, the light emitting area EA can be disposed relatively up, and the circuit area can be disposed relatively down.

Referring to FIG. 10, for the bankless structure, the bank BANK can be disposed to correspond to the circuit area. On the other hand, the bank BANK can be etched and removed in an area corresponding to the light emitting area EA. In the horizontal direction where the light emitting areas EA are disposed, the bank BANK can be etched and removed. For example, the bank BANK may not be disposed between the first light emitting area EA_R and the second light emitting area EA_G. In addition, the bank BANK may not be disposed between the second light emitting area EA_G and the third light emitting area EA_B.

As shown in FIG. 10, after the bank BANK is disposed, the tandem intermediate layer EL can be deposited on an entire surface. Further, the tandem intermediate layer EL can include a first intermediate layer EL1, a first charge generation layer CGL1, a second intermediate layer EL2, a second charge generation layer CGL2 and a third intermediate layer EL3. As shown, the first intermediate layer EL1 can also be disposed in contact with the overcoating layer OC in the first non-light emitting area NEA1.

Referring to FIG. 10, the cathode electrode CAT can be disposed to cover the tandem intermediate layer EL. In addition, as shown in FIG. 10, a first distance d1 from the side surface of the current removal line CRL to the first charge generation layer CGL1 can be shorter than a second distance d2 from the upper surface of the current removal line CRL to the first charge generation layer CGL1. As an electromagnetic field is formed between the current removal line CRL and the first charge generation layer CGL1, leakage current flowing through the first charge generation layer CGL1 can be removed through the current removal line CRL.

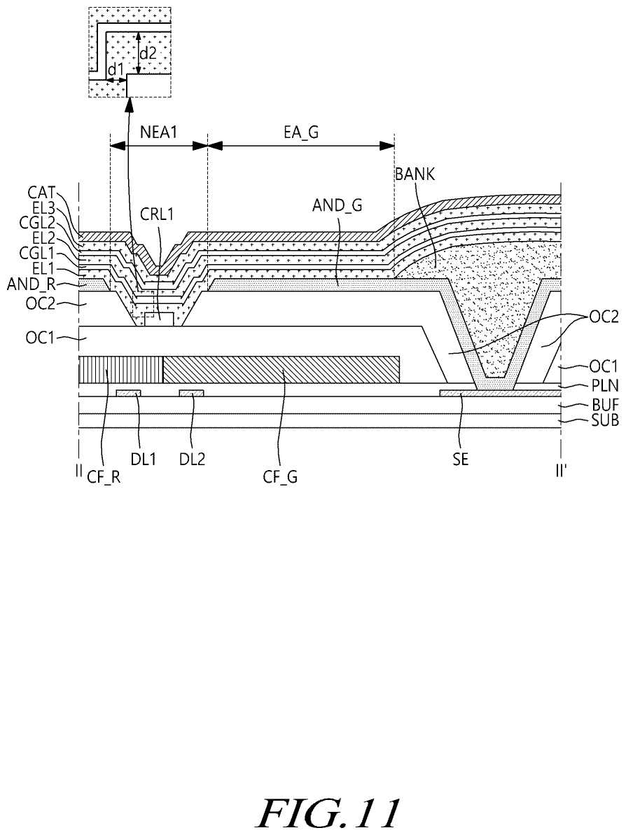

Next, FIG. 11 illustrates a portion of the cross-sectional view of the display device 100 including the current removal line CRL. Referring to FIG. 11, a substrate SUB can be disposed at the bottom of the display panel 110.

As shown in FIG. 11, a buffer layer BUF can be disposed on the substrate SUB and can be an insulating layer. A first data line DL1 and a second data line DL2 can also be disposed on the buffer layer BUF, but can be disposed in the non-light emitting area NEA.

Referring to FIG. 11, a source electrode SE can be disposed on the buffer layer BUF and can be the source electrode SE of a driving transistor. Alternatively, the source electrode SE can be an electrode which is electrically connected to the source electrode SE of a driving transistor.

As shown in FIG. 11, a planarization layer PLN can be disposed to cover the buffer layer BUF, the first data line DL1, the second data line DL2 and a reference voltage line RVL. The planarization layer PLN can be an insulating layer and can include a contact hole for electrically connecting electrodes disposed on and under the planarization layer PLN.

Referring to FIG. 11, a first color filter CF_R can be disposed on the planarization layer PLN and can be a color filter for expressing red. The first color filter CF_R can be disposed between a first overcoating layer OC1 and the substrate SUB to overlap a first anode electrode AND_R.

As shown in FIG. 11, a second color filter CF_G can be disposed on the planarization layer PLN and can be a color filter for expressing green. The second color filter CF_G can also be disposed between the first overcoating layer OC1 and the substrate SUB to overlap a second anode electrode AND_G.

Further, the second color filter CF_G can be disposed in contact with the first color filter CF_R. The second color filter CF_G can also be disposed side by side with the first color filter CF_R. Referring to FIG. 11, the first overcoating layer OC1 can be disposed to cover the first color filter CF_R, the second color filter CF_G and the planarization layer PLN. The first overcoating layer OC1 can also include a contact hole for electrically connecting electrodes disposed on and under the first overcoating layer OC1.

In addition, a second overcoating layer OC2 can be disposed on the first overcoating layer OC1 and can include a contact hole for electrically connecting electrodes disposed on and under the second overcoating layer OC2. As shown in FIG. 11, the second overcoating layer OC2 can be disposed on the first overcoating layer OC1, and can include a contact hole which is disposed in the first non-light emitting area NEA1.

Further, the current removal line CRL can be disposed in contact with the first overcoating layer OC1 in the contact hole of the second overcoating layer OC2. Referring to FIG. 11, the first anode electrode AND_R can be disposed on the second overcoating layer OC2. The first anode electrode AND_R can be disposed on the second overcoating layer OC2 to overlap the first light emitting area EA_R.

Also, the second anode electrode AND_G can be disposed on the second overcoating layer OC2. The second anode electrode AND_G can be disposed in contact with the source electrode SE through the contact hole of the second overcoating layer OC2. In addition, the second anode electrode AND_G can be disposed on the first overcoating layer OC1 to overlap the second light emitting area EA_G.

The BANK shown in FIG. 11 can be disposed in a bankless structure like the bank BANK shown in FIG. 10. After the bank BANK is deposited on an entire surface, a portion of the bank BANK corresponding to the light emitting area EA and a portion of the bank BANK corresponding to the non-light emitting area NEA can be removed by being etched. Referring to FIG. 11, the bank BANK may not be disposed in the first non-light emitting area NEA1.

Referring again to FIG. 11, after the bank BANK is disposed, the tandem intermediate layer EL can be deposited on an entire surface. In addition, the tandem intermediate layer EL can include a first intermediate layer EL1, a first charge generation layer CGL1, a second intermediate layer EL2, a second charge generation layer CGL2 and a third intermediate layer EL3. Further, the first intermediate layer EL1 can be disposed to cover the second overcoating layer OC2 and the current removal line CRL in the first non-light emitting area NEA1.

Referring to FIG. 11, the first intermediate layer EL1 can be disposed in contact with the first overcoating layer OC1 in the first non-light emitting area NEA1. Also, the cathode electrode CAT can be disposed to cover the tandem intermediate layer EL.

As shown in FIG. 11, a first distance d1 from the side surface of the current removal line CRL to the first charge generation layer CGL1 can be shorter than a second distance d2 from the upper surface of the current removal line CRL to the first charge generation layer CGL1. As an electromagnetic field is formed between the current removal line CRL and the first charge generation layer CGL1, leakage current flowing through the first charge generation layer CGL1 can be removed through the current removal line CRL.

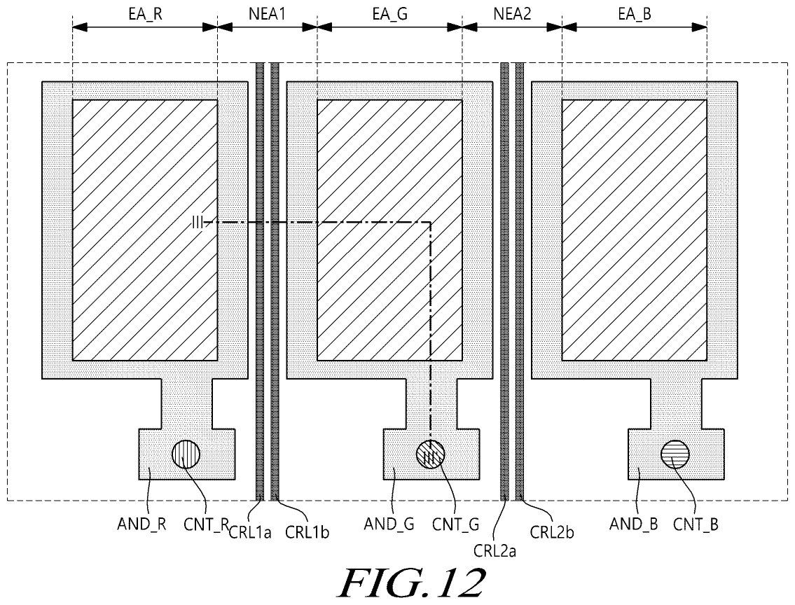

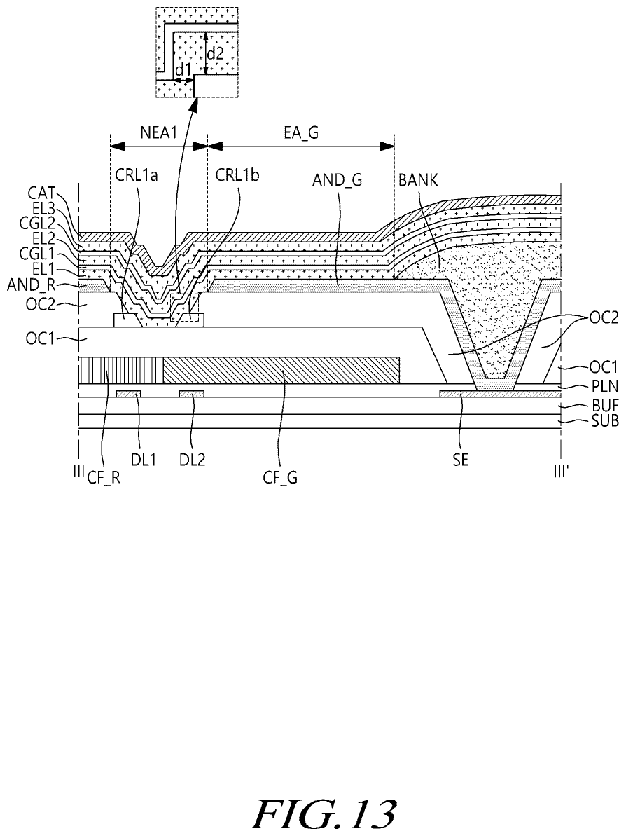

Next, FIG. 12 is a diagram of current removal lines CRL disposed in a non-light emitting area NEA, and FIG. 13 is a cross-sectional view of the current removal lines CRL disposed in the non-light emitting area NEA according to embodiments of the present disclosure.

Referring to FIG. 12, two current removal lines CRL can be disposed between light emitting areas EA. In more detail, two current removal lines CRL can be disposed in a first non-light emitting area NEA1, and current removal lines CRL can be disposed in a second non-light emitting area NEA2. FIG. 12 also illustrates a line III-III′ and FIG. 13 shows a cross-sectional view taken along the line III-III′.

The current removal lines CRL shown in FIG. 13 have a structural difference from the current removal line CRL shown in FIG. 11. Among the components of the display device 100 shown in FIG. 13, descriptions of features that are the same as those of the components of the display device 100 shown in FIG. 11 are omitted.

Referring to FIG. 13, a first current removal line CRL1a and a second current removal line CRL1b can be disposed in the contact hole of the second overcoating layer OC2. In particular, the first current removal line CRL1a can be disposed in the contact hole of the second overcoating layer OC2 to be adjacent to the first light emitting area EA_R, and the second current removal line CRL1b can be disposed in the contact hole of the second overcoating layer OC2 to be adjacent to the second light emitting area EA_G.

As shown in FIG. 13, the left portion of the first current removal line CRL1a can be disposed to overlap the second overcoating layer OC2, and the right portion of the first current removal line CRL1a can be disposed to overlap the tandem intermediate layer EL. As shown, the right portion of the second current removal line CRL1b can be disposed to overlap the second overcoating layer OC2, and the left portion of the second current removal line CRL1b can be disposed to overlap the tandem intermediate layer EL.

In addition, the second overcoating layer OC2, the first anode electrode AND_R, the second anode electrode AND_G and the bank BANK shown in FIG. 13 can be the same as the second overcoating layer OC2, the first anode electrode AND_R, the second anode electrode AND_G and the bank BANK shown in FIG. 11. Namely, the bank BANK shown in FIG. 13 can also be disposed in a bankless structure shown in FIG. 11.

Referring to FIG. 11, one current removal line CRL is disposed in the non-light emitting area NEA, and referring to FIG. 13, two current removal lines CRL are disposed in the non-light emitting area NEA. As the resolution of the display device 100 increases, the spacing between subpixels becomes narrower. Accordingly, a short circuit can occur between the current removal lines CRL and the anode electrodes AND. When current removal lines CRL are disposed like the current removal lines CRL shown in FIG. 13, the possibility of a short circuit between the current removal lines CRL and the anode electrodes AND can be prevented.

Next, a process of forming the first current removal line CRL1a and the second current removal line CRL1b can be as follows. After one current removal line CRL is disposed on the first overcoating layer OC1, the second overcoating layer OC2 can be disposed to cover the current removal line CRL. In addition, the second overcoating layer OC2 can include a contact hole which exposes the center portion of the current removal line CRL. A wet etching process can then be performed on the current removal line CRL, and the one current removal line CRL can become two current removal lines CRL. Further, a portion of the second overcoating layer OC2 which overlaps the current removal line CRL can have an undercut structure, and then, an ashing process can be performed on the corresponding portion. Accordingly, the side surface of the first current removal line CRL1a and the side surface of the second current removal line CRL1b can be exposed in an upward direction. Also, the tandem intermediate layer EL can be disposed to cover the first current removal line CRL1a and the second current removal line CRL1b.

Referring again to FIG. 13, the tandem intermediate layer EL can include a first intermediate layer EL1, a first charge generation layer CGL1, a second intermediate layer EL2, a second charge generation layer CGL2 and a third intermediate layer EL3. The first intermediate layer EL1 can also be disposed in contact with the first overcoating layer OC1 and the second overcoating layer OC2 in the first non-light emitting area NEA1. The cathode electrode CAT can also be disposed to cover the tandem intermediate layer EL.

As shown in FIG. 13, a first distance d1 from the side surface of the second current removal line CRL1b to the first charge generation layer CGL1 can be shorter than a second distance d2 from the upper surface of the second current removal line CRL1b to the first charge generation layer CGL1. As an electromagnetic field is formed between the second current removal line CRL1b and the first charge generation layer CGL1, leakage current flowing through the first charge generation layer CGL1 can be removed through the second current removal line CRL1b. The above feature is also applied the same to the first current removal line CRL1a.

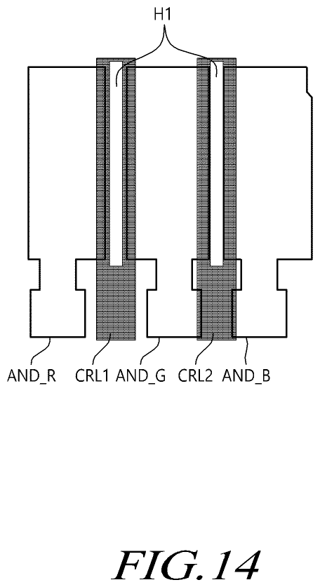

Next, FIGS. 14 to 17 are diagrams of current removal lines CRL disposed to overlap anode electrodes AND according to embodiments of the present disclosure. Referring to FIGS. 14 to 17, a portion of a current removal line CRL can be disposed to overlap an anode electrode AND. In this instance, in order to prevent a short circuit between the current removal line CRL and the anode electrode AND, an insulating layer can be disposed between the current removal line CRL and the anode electrode AND.

As shown in FIGS. 14 to 17, the side surfaces of the current removal line CRL can be disposed between the first anode electrode AND_R and the second anode electrode AND_G. Also, a first current removal line CRL1 can be disposed between the first anode electrode AND_R and the second anode electrode AND_G, and a second current removal line CRL2 can be disposed between the second anode electrode AND_G and the third anode electrode AND_B.

As shown in FIGS. 14 to 16, the first current removal line CRL1 and the second current removal line CRL2 can include grooves H1, H2 and H3. In particular, the grooves H1, H2 and H3 can be disposed between the first anode electrode AND_R and the second anode electrode AND_G. Also, the grooves H1, H2 and H3 can be disposed between the second anode electrode AND_G and the third anode electrode AND_B.

Referring to FIG. 14, the shape of the first groove H1 can be one rectangle, and the first groove H1 having the shape of one rectangle can be disposed between the anode electrodes AND. Further, the side surfaces of the current removal line CRL including the first groove H1 can be disposed in the non-light emitting area NEA. Accordingly, the side surfaces of the current removal line CRL can be disposed adjacent to a charge generation layer (not shown).

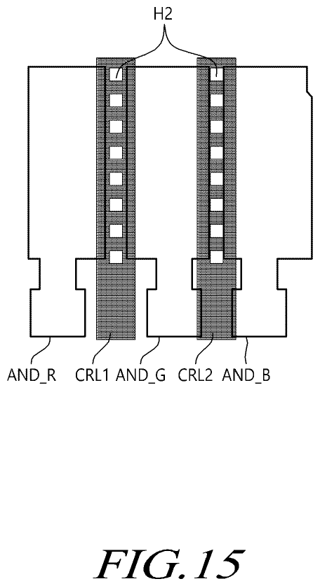

Referring to FIG. 15, the shape of a plurality of second groove H2 can be a plurality of squares. The second grooves H2 having the shape of squares disposed in a line can be disposed between the anode electrodes AND. In addition, the side surfaces of the current removal lines CRL including the second grooves H2 can be disposed in the non-light emitting area NEA. Accordingly, the side surfaces of the current removal line CRL can be disposed adjacent to a charge generation layer (not shown).

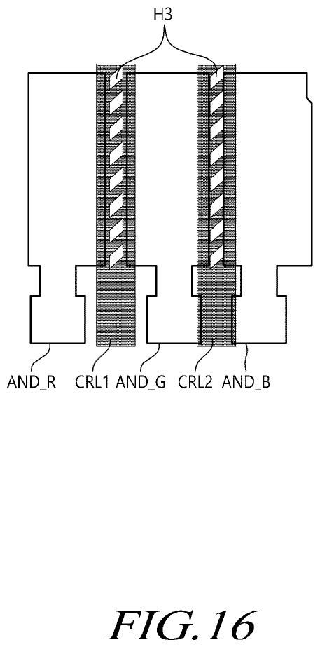

Referring to FIG. 16, the shape of a plurality of third groove H3 can be a plurality of trapezoids or diamonds. The third grooves H3 having the shape of trapezoids or diamonds disposed in a line can be disposed between the anode electrodes AND. Further, the side surfaces of the current removal lines CRL including the third grooves H3 can be disposed in the non-light emitting area NEA. Accordingly, the side surfaces of the current removal line CRL can be disposed adjacent to a charge generation layer (not shown).

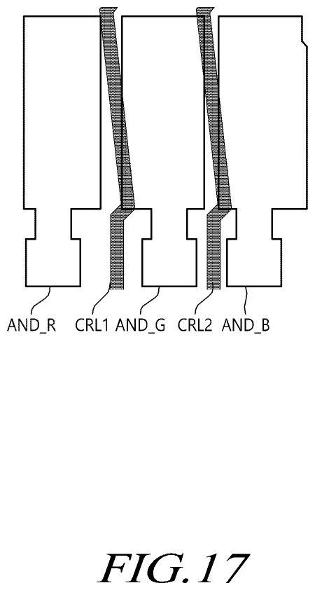

Referring to FIG. 17, the current removal lines CRL can be disposed in an oblique direction between the anode electrodes AND. In addition, the left upper end portion of the first current removal line CRL1 can be disposed to overlap the first anode electrode AND_R, and the right lower end portion of the first current removal line CRL1 can be disposed to overlap the second anode electrode AND_G. Further, the side surfaces of the current removal lines CRL disposed in the oblique direction can be disposed in the non-light emitting area NEA. Accordingly, the side surfaces of the current removal line CRL can be disposed adjacent to a charge generation layer.

As shown in FIGS. 14 to 17, when the current removal lines CRL include the grooves H1, H2 and H3 or the current removal lines CRL are disposed in the oblique direction, leakage current can be removed through the current removal lines CRL even when a process deviation occurs. When a process deviation occurs, the side surface of the current removal line CRL may not be exposed to the non-light emitting area NEA. In this instance, the side surface of the current removal line CRL and the charge generation layer CGL may not be disposed adjacent to each other.

As shown in FIGS. 14 to 17, when the current removal lines CRL include the grooves H1, H2 and H3 or the current removal lines CRL are disposed in the oblique direction, a process deviation can be reduced. As a process deviation is reduced, the side surface of the current removal line CRL can be stably disposed in the non-light emitting area NEA.

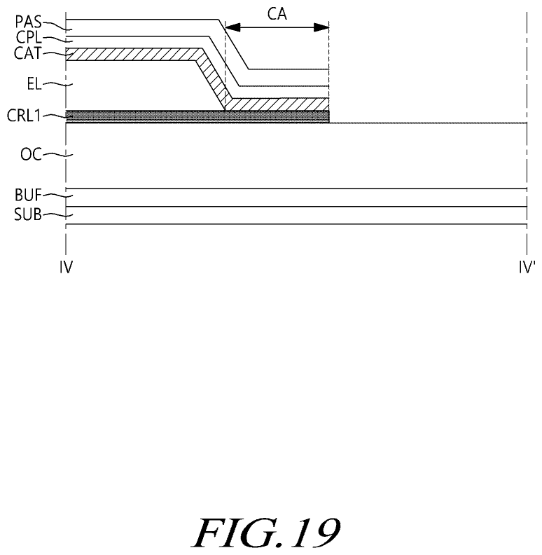

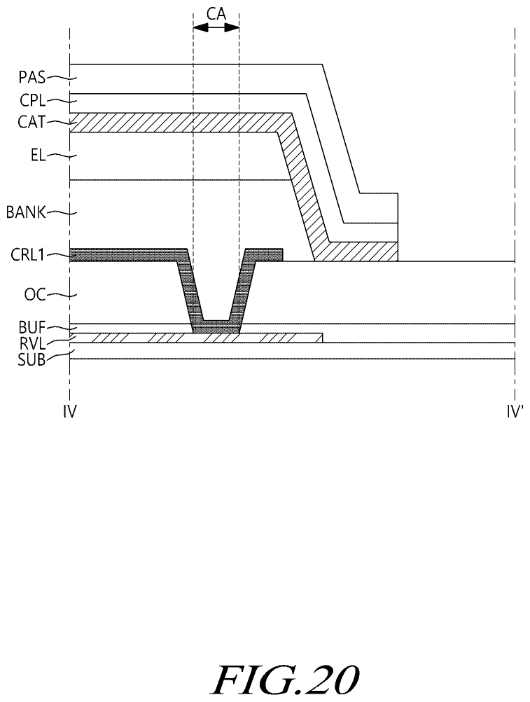

Next, FIG. 18 is a diagram of current removal lines CRL disposed in a display panel 110 according to embodiments of the present disclosure, and FIGS. 19 and 20 are diagrams of current removal lines CRL in contact areas CA according to embodiments of the present disclosure.

Referring to FIG. 18, the display panel 110 can be electrically connected to a data driving circuit 130 in a pad area PA. In addition, the display panel 110 can include four sides, and the pad area PA can be one area among the four sides of the display panel 110. The remaining three sides of the display panel 110 can be non-pad areas (NPA).

In addition, current removal lines CRL can be disposed in a stripe shape to extend from the pad area PA to a contact area CA. In addition, FIG. 18 illustrates a line IV-IV′ which crosses the contact area CA, and FIGS. 19 and 20 show cross-sectional views taken along the line IV-IV′. Further, the current removal line CRL can be supplied with a low voltage from the contact area CA.

Referring to FIG. 19, a buffer layer BUF can be disposed on a substrate SUB, and overcoating layer OC can be disposed on the buffer layer BUF, and a first current removal line CRL1 can be disposed on the overcoating layer OC. In addition, a tandem intermediate layer EL can be disposed to overlap the first current removal line CRL1, and a cathode electrode CAT can be disposed to cover the tandem intermediate layer EL and the first current removal line CRL1. Further, the left portion of the cathode electrode CAT can be disposed to cover the tandem intermediate layer EL, and the right portion of the cathode electrode CAT can be disposed to cover the first current removal line CRL1.

As shown in FIG. 19, the first current removal line CRL1 can be disposed in contact with the cathode electrode CAT in the contact area CA. Also, the cathode electrode CAT can be an electrode which is supplied with a base voltage. Because the first current removal line CRL1 is disposed in contact with the cathode electrode CAT, the first current removal line CRL1 can be supplied with the base voltage.

Referring to FIG. 20, a reference voltage line RVL can be disposed between the substrate SUB and the buffer layer BUF, and an overcoating layer OC can be disposed on the buffer layer BUF. Also, a first current removal line CRL1 can be disposed on the overcoating layer OC, and the first current removal line CRL1 can be disposed in contact with the reference voltage line RVL through a contact hole of the overcoating layer OC. Further, the reference voltage line RVL can be supplied with a reference voltage. Because the first current removal line CRL1 is disposed in contact with the reference voltage line RVL, the first current removal line CRL1 can be supplied with the reference voltage.

Referring to FIG. 20, a bank BANK can be disposed to cover the first current removal line CRL1, and a tandem intermediate layer EL can be disposed on the bank BANK. Also, a cathode electrode CAT can be disposed to cover portions of the tandem intermediate layer EL, the bank BANK and the overcoating layer OC. In addition, the first current removal line CRL1 shown in FIGS. 19 and 20 can include metal oxide such as indium-tin oxide (ITO), indium-zinc oxide (IZO), indium-tin-zinc oxide (ITZO) and indium-gallium-zinc oxide (IGZO).

Referring to FIGS. 19 and 20, a capping layer CPL can be disposed on the cathode electrode CAT, and a passivation layer PAS can be disposed on the capping layer CPL. The capping layer CPL and the passivation layer PAS can be layers for protecting the tandem intermediate layer EL. That is, the capping layer CPL and the passivation layer PAS can be an encapsulation layer.

In addition, the passivation layer PAS can be disposed to be thicker than the capping layer CPL. For example, the thickness of the capping layer CPL can have 300 Angstroms, and the thickness of the passivation layer PAS can be 2300 Angstroms.

Unlike the illustration of FIGS. 19 and 20, only the capping layer CPL can be disposed without the passivation layer PAS. In this instance, the capping layer CPL can serve as an encapsulation layer. Also, the thickness of the capping layer CPL can be 3000 Angstroms to 5000 Angstroms.

Next, FIG. 21 is a diagram of a current removal line CRL disposed in a display panel 110 according to embodiments of the present disclosure. As shown in FIG. 21, the current removal line CRL can be disposed in the shape of a mesh.

In addition, FIG. 21 illustrates a cross-sectional view taken along the line V-V′. Referring to FIG. 21, a reference voltage line RVL can be disposed between a substrate SUB and a buffer layer BUF, and an overcoating layer OC can be disposed on the buffer layer BUF. Further, a current removal line CRL can be disposed on the overcoating layer OC, and the current removal line CRL can be disposed in contact with the reference voltage line RVL through a contact hole of the overcoating layer OC. In addition, the reference voltage line RVL can be supplied with a reference voltage. Because the current removal line CRL is disposed in contact with the reference voltage line RVL, the current removal line CRL can be supplied with the reference voltage.

The current removal line CRL shown in FIG. 21 can include metal oxide such as indium-tin oxide (ITO), indium-zinc oxide (IZO), indium-tin-zinc oxide (ITZO) and indium-gallium-zinc oxide (IGZO). The current removal line CRL shown in FIG. 21 can also include doped amorphous silicon (a-Si), doped polycrystalline silicon (poly-Si), etc.

Referring to FIG. 21, the current removal line CRL can be disposed to surround a light emitting area. For example, four subpixels can share one reference voltage line RVL. Also, one reference voltage line RVL can extend long in a vertical direction, but wirings can extended therefrom in a horizontal direction at regular intervals.

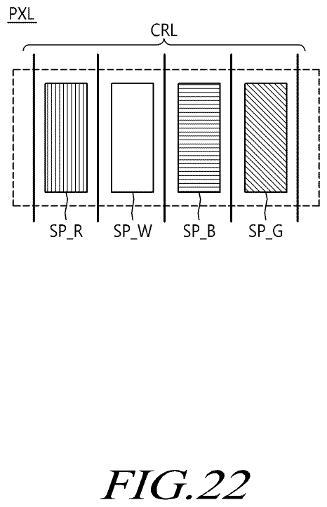

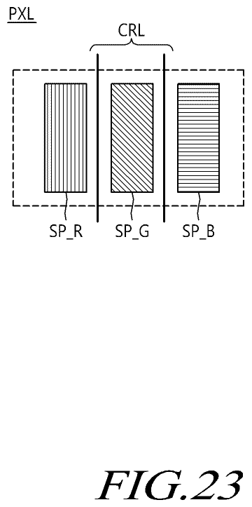

Next, FIGS. 22 and 23 are diagrams of the disposition of current removal lines CRL according to embodiments of the present disclosure. Referring to FIG. 22, one pixel PXL can include four subpixels SP including a red subpixel SP_R, a white subpixel SP_W, a blue subpixel SP_B and a green subpixel SP_G, for example. A plurality of current removal lines CRL can also be disposed between a plurality of subpixels.

As shown in FIG. 23, one pixel PXL can include three subpixels SP including a red subpixel SP_R, a green subpixel SP_G and a blue subpixel SP_B. A plurality of current removal lines CRL can also be disposed between the green subpixel SP_G and the red subpixel SP_R. In addition, a plurality of current removal lines CRL can be disposed between the green subpixel SP_G and the blue subpixel SP_B.

Further, a lateral leakage current phenomenon is likely to occur in the green subpixel SP_G adjacent to the red subpixel SP_R when the red subpixel SP_R emits light. In addition, a lateral leakage current phenomenon is likely to occur in the green subpixel SP_G adjacent to the blue subpixel SP_B when the blue subpixel SP_B emits light.

Therefore, the current removal lines CRL can be disposed only between the green subpixel SP_G and the red subpixel SP_R or between the green subpixel SP_G and the blue subpixel SP_B. In this instance, because the number of current removal lines CRL can be reduced, the aperture ratio of the display device 100 can be improved.

A brief description of the embodiments of the present disclosure described above is as follows.

Embodiments of the present disclosure can provide a display device including a substrate including a first light emitting area and a second light emitting area; a first overcoating layer disposed on the substrate; a first anode electrode disposed on the first overcoating layer to overlap the first light emitting area; a second anode electrode disposed on the first overcoating layer to overlap the second light emitting area; a current removal line disposed in a first non-light emitting area as an area between the first light emitting area and the second light emitting area; a first intermediate layer disposed to cover the current removal line, and including a first emitting layer; a charge generation layer disposed on the first intermediate layer; a second intermediate layer disposed on the charge generation layer, and including a second emitting layer; and a cathode electrode disposed on the second intermediate layer.

The display device can further include a bank disposed between the current removal line and the first overcoating layer. The display device can further include a bank disposed in the first non-light emitting area, and including an etched area which is formed as the bank is partially removed between the first anode electrode and the second anode electrode, and the current removal line can be disposed in the etched area of the bank. The bank can be made of a transparent material.

The first intermediate layer can be disposed in contact with the first overcoating layer in the first non-light emitting area. The display device can further include a bank covering the first anode electrode, and not disposed in the first non-light emitting area. The display device can further include a second overcoating layer disposed on the first overcoating layer, and including a contact hole which is disposed in the first non-light emitting area, and the current removal line can be disposed in contact with the first overcoating layer in the contact hole of the second overcoating layer.

The first intermediate layer can be disposed to cover the second overcoating layer and the current removal line in the first non-light emitting area. The display device can further include a second current removal line disposed parallel to a first current removal line, which is the current removal line, in the first non-light emitting area.

The first current removal line can be disposed in the contact hole to be adjacent to the first light emitting area, and the second current removal line can be disposed in the contact hole to be adjacent to the second light emitting area. A side surface of the current removal line can be disposed adjacent to the charge generation layer. A distance from the side surface of the current removal line to the charge generation layer can be shorter than a distance from an upper surface of the current removal line to the charge generation layer.

The substrate can further include a pad area and a non-pad area different from the pad area, and the current removal line can be disposed in contact with the cathode electrode in the non-pad area. The display device can further include a reference voltage line disposed between the substrate and the current removal line, the substrate can include a pad area and a non-pad area different from the pad area, and the current removal line can be disposed in contact with the reference voltage line in the non-pad area.

In addition, the display device can further include a reference voltage line disposed between the substrate and the current removal line, and the current removal line can be disposed in contact with the reference voltage line in the first non-light emitting area. The current removal line can be disposed in an oblique direction between the first anode electrode and the second anode electrode.

A left upper end portion of the current removal line can overlap the first anode electrode, and a right lower end portion of the current removal line can be disposed to overlap the second anode electrode. The current removal line can be disposed in a stripe shape or a mesh shape.

Further, the display device can also include a plurality of current removal lines including the current removal line, the substrate can include a plurality of light emitting areas, and the current removal lines can be disposed between the light emitting areas.

In addition, the first light emitting area can be an area which emits green light and the second light emitting area can be an area which emits red light or blue light, and the current removal line can be disposed adjacent to the first light emitting area which emits green light.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

What is claimed is:

1. A display device comprising:
a substrate including a first light emitting area and a second light emitting area;
a first overcoating layer disposed on the substrate;
a first anode electrode disposed on the first overcoating layer and overlapping the first light emitting area;
a second anode electrode disposed on the first overcoating layer and overlapping the second light emitting area;
a current removal line disposed in a first non-light emitting area between the first light emitting area and the second light emitting area and configured to remove a leakage current generated from the first light emitting area and leaking into the second light emitting area;
a first intermediate layer disposed to cover the current removal line, and including a first emitting layer;
a charge generation layer disposed on the first intermediate layer;
a second intermediate layer disposed on the charge generation layer, and including a second emitting layer; and
a cathode electrode disposed on the second intermediate layer.

2. The display device of claim 1, further comprising:
a bank disposed between the current removal line and the first overcoating layer.

3. The display device of claim 1, further comprising:
a bank disposed in the first non-light emitting area, and including an etched area between the first anode electrode and the second anode electrode,
wherein the current removal line is disposed in the etched area of the bank.

4. The display device of claim 3, wherein the bank includes a transparent material.

5. The display device of claim 1, wherein the first intermediate layer contacts the first overcoating layer in the first non-light emitting area.

6. The display device of claim 5, further comprising:
a bank covering the first anode electrode, and not being disposed in the first non-light emitting area.

7. The display device of claim 1, further comprising:
a second overcoating layer disposed on the first overcoating layer, and including a contact hole disposed in the first non-light emitting area,
wherein the current removal line contacts the first overcoating layer in the contact hole of the second overcoating layer.

8. The display device of claim 7, wherein the first intermediate layer is disposed to cover the second overcoating layer and the current removal line in the first non-light emitting area.

9. The display device of claim 7, further comprising:
an additional current removal line disposed parallel to the removal line in the first non-light emitting area.

10. The display device of claim 9, wherein
the current removal line is disposed in the contact hole to be adjacent to the first light emitting area, and
the additional current removal line is disposed in the contact hole to be adjacent to the second light emitting area.

11. The display device of claim 1, wherein a side surface of the current removal line is disposed adjacent to the charge generation layer.

12. The display device of claim 11, wherein a distance from the side surface of the current removal line to the charge generation layer is shorter than a distance from an upper surface of the current removal line to the charge generation layer.

13. The display device of claim 1, wherein
the substrate further includes a pad area and a non-pad area, and
the current removal line contacts the cathode electrode in the non-pad area.

14. The display device of claim 1, further comprising:
a reference voltage line disposed between the substrate and the current removal line,
wherein the substrate includes a pad area and a non-pad area, and
wherein the current removal line contacts the reference voltage line in the non-pad area.

15. The display device of claim 1, further comprising:
a reference voltage line disposed between the substrate and the current removal line,
wherein the current removal line contacts the reference voltage line in the first non-light emitting area.

16. The display device of claim 1, wherein the current removal line is disposed in an oblique direction between the first anode electrode and the second anode electrode.

17. The display device of claim 16, wherein
a left upper end portion of the current removal line overlaps the first anode electrode, and
a right lower end portion of the current removal line overlaps the second anode electrode.

18. The display device of claim 1, wherein the current removal line has a stripe shape or a mesh shape.

19. The display device of claim 1, wherein the currently removal line includes a plurality of current removal lines,
wherein the substrate includes a plurality of light emitting areas, and
wherein the plurality of current removal lines are disposed between the plurality of light emitting areas.

20. The display device of claim 1, wherein
the first light emitting area emits green light, and the second light emitting area emits red light or blue light, and
the current removal line is disposed adjacent to the first light emitting area which emits green light.
